(19) United States
(12) Patent Application Publication
(10) Pub. No.: US 2025/0046772 A1
(43) Pub. Date: Feb. 6, 2025

(54) SUBSTRATE STRUCTURE FOR TRANSCRIPTION OF SEMICONDUCTOR LIGHT EMITTING DEVICE FOR PIXEL, AND DISPLAY DEVICE COMPRISING SAME

(71) Applicants: LG ELECTRONICS INC., Seoul (KR); LG DISPLAY CO., LTD., Seoul (KR)

(72) Inventors: Younho HEO, Seoul (KR); Hooyoung SONG, Seoul (KR)

(73) Assignees: LG ELECTRONICS INC., Seoul (KR); LG DISPLAY CO., LTD., Seoul (KR)

(21) Appl. No.: 18/717,799

(22) PCT Filed: Dec. 8, 2022
(86) PCT No.: PCT/KR2022/019935

§ 371 Date: Jun. 7, 2024

(30) Foreign Application Priority Data
Dec. 8, 2021 (KR) 10-2021-0175097
Dec. 8, 2022 (KR) 10-2022-0170239

(51) Int. Cl. H01L 25/13; H01L 33/48; H01L 33/62

(52) U.S. Cl. CPC H01L 25/13; H01L 33/483; H01L 33/62

(57) ABSTRACT

The substrate structure for transferring the pixel semiconductor light emitting device according to the embodiment may include a substrate having a plurality of assembly wiring; a partition wall disposed on the substrate and having an assembly hole into which a predetermined semiconductor light emitting device is assembled; and the partition wall may include a porous structure.

### TECHNICAL FIELD

The embodiment relates to a substrate structure for transferring a semiconductor light emitting device for pixels and a display device including the same.

### BACKGROUND ART

Large-area displays include liquid crystal displays (LCDs), OLED displays, and Micro-LED displays.

Micro-LED display is a display that uses micro-LED, a semiconductor light emitting device with a diameter or cross-sectional area of 100 μm or less, as a display device.

Micro-LED displays use micro-LED, a semiconductor light emitting device, as a display device, so they have excellent performance in many characteristics such as contrast ratio, response speed, color reproduction rate, viewing angle, brightness, resolution, lifespan, luminous efficiency, and luminance.

In particular, the micro-LED display has the advantage of being able to freely adjust the size and resolution and implement a flexible display because the screen may be separated and combined in a modular manner.

However, because large micro-LED displays require more than millions of micro-LEDs, there is a technical problem that makes it difficult to quickly and accurately transfer micro-LEDs to the display panel.

Transfer technologies that have been recently developed include the pick and place process, laser lift-off method, or self-assembly method.

Among these, the self-assembly method is a method in which the semiconductor light emitting device finds its assembly position within the fluid on its own, and is an advantageous method for implementing a large-screen display device.

However, as the substrate on which the semiconductor light emitting device is assembled is formed with a large area, the phenomenon of bending of the substrate due to gravity occurs. Because of this, the assembly rate is different depending on the area of the substrate, and the problem of a decrease in the overall assembly rate is being studied. Therefore, there is a need for technology to prevent warping of large-area substrates.

### DISCLOSURE

### Technical Problem

The embodiment objects to solve the above-mentioned problems and other problems.

Another object of the embodiment is to prevent warping of the transfer substrate.

Additionally, another object of the embodiment is to improve the self-assembly rate of the semiconductor light emitting device.

In addition, another object of the embodiment is to have a uniform assembly rate depending on the area within the large-area substrate.

Additionally, another object of the embodiment is to prevent the semiconductor light emitting device from being adsorbed to areas other than the assembly hole.

In addition, another object of the embodiment is to improve the adhesion of the deposition process in the display process after assembly of the semiconductor light emitting device.

The technical problems of the embodiments are not limited to those described in this item and include those that may be understood through the description of the invention.

### Technical Solution

According to an embodiment, a substrate structure for transferring a semiconductor light emitting device for pixel may include a substrate having a plurality of assembly wiring, a partition wall disposed on the substrate and having an assembly hole where a predetermined semiconductor light emitting device is assembled and the partition wall may include a porous structure.

Also, in an embodiment, the partition wall includes a first area disposed close to the substrate and a second area disposed far from the substrate, depending on the height from the substrate, and a density of pores in the first area and a density of pores in the second area may be different.

Also, in an embodiment, a size of the pores in the first area may be larger than a size of the pores in the second area.

Also, in an embodiment, a number of pores in the first area may be greater than a number of pores in the second area.

Also, in an embodiment, a size of the pores in the first area may be smaller than a size of the pores in the second area.

Also, in an embodiment, a number of pores in the first area may be less than a number of pores in the second area.

Also, in an embodiment, a concavo-convex structure may be formed on a surface of the partition wall due to the porous structure.

Also, in an embodiment, a density of pores adjacent to a central portion of the substrate may be different from a density of pores adjacent to an edge portion of the substrate.

Also, in an embodiment, a density of pores adjacent to a central portion of the substrate may be greater than a density of pores adjacent to an edge portion of the substrate.

Also, in an embodiment, a density of pores adjacent to a central portion of the substrate may be smaller than a density of pores adjacent to an edge portion of the substrate.

Additionally, in an embodiment, a density of pores may increase from the partition wall adjacent to one end of the substrate to the partition wall adjacent to another end of the substrate.

In another embodiment, a density of pores may decrease from a central portion of the substrate and the adjacent partition wall to an edge portion of the substrate and the adjacent partition wall.

A display device of a semiconductor light emitting device according to an embodiment may include a substrate structure for transferring a semiconductor light emitting device for pixel and a semiconductor light emitting device disposed in the assembly hole.

### Advantageous Effects

The substrate structure for transferring a semiconductor light emitting device for pixels according to the embodiment and the display device including the same have the technical effect of improving the assembly rate when assembling a semiconductor light emitting device to a panel substrate.

In addition, in the example, there is a technical effect of preventing substrate bending during face-down self-assembly.

For example, the embodiment may control the density of pores within the partition wall to prevent the bending of the substrate by offsetting the downward convexity of the central portion of the substrate due to gravity through substrate shrinkage.

In addition, in the example, there is a technical effect of preventing substrate bending during face-up self-assembly.

For example, the embodiment may control the density of pores in the partition wall to prevent the bending of the substrate by offsetting the phenomenon in which the central portion of the substrate is concave downward due to gravity through substrate shrinkage.

Additionally, the embodiment has the technical effect of ensuring a uniform assembly rate regardless of area in a large-area substrate.

For example, since self-assembly proceeds in a flat form in the embodiment, the distance between the assembly magnet and the substrate is constant, allowing for a uniform assembly rate regardless of the area of the substrate.

In addition, the embodiment has the technical effect of allowing the semiconductor light emitting device to be placed in the assembly hole without being adsorbed to the surface of the partition wall during self-assembly.

For example, a semiconductor light emitting device may not be adsorbed to the surface of a partition wall due to the concavo-convex structure formed by pores on the surface of the partition wall.

Additionally, in the embodiment, when the display process proceeds after the assembly process, there is a technical effect of increasing the adhesion of the deposition process.

For example, the concavo-convex structure formed by the pores on the surface of the partition wall can increase adhesion during the deposition process of metal films, organic films, and insulating films.

Additionally, in the embodiment, there is a technical effect of preventing the generation of tension depending on the order in which the substrate is immersed in the fluid.

For example, the density of pores in the area of the substrate that is first submerged in the fluid is smaller than the density of pores in the area that is submerged later, so that tension can be minimized when the substrate is submerged in the fluid.

Additional scope of applicability of the embodiments will become apparent from the detailed description below. However, since various changes and modifications within the spirit and scope of the embodiments may be clearly understood by those skilled in the art, the detailed description and specific embodiments, such as preferred embodiments, should be understood as being given by way of example only.

### DESCRIPTION OF DRAWINGS

FIG. 1 is an exemplary diagram of the living room of a house where a display device according to an embodiment is placed.

FIG. 2 is a block diagram schematically showing a display device according to an embodiment.

FIG. 3 is a circuit diagram showing an example of the pixel of FIG. 2.

FIG. 4 is an enlarged view of the first panel area in the display device of FIG. 1.

FIG. 5 is a cross-sectional view taken along line B1-B2 in area A2 of FIG. 4.

FIG. 6 is an example of a light emitting device according to an embodiment being assembled on a substrate by a self-assembly method.

FIG. 7 is a conceptual diagram showing defect issues in panel assembly of an undisclosed internal semiconductor light emitting device.

FIG. 8 is a cross-sectional view of a substrate structure for transferring a semiconductor light emitting device for pixels and a display device including the same according to the first embodiment.

FIG. 9 is a cross-sectional view of a substrate structure for transferring a semiconductor light emitting device for pixels and a display device including the same according to the second embodiment.

FIG. 10 is a conceptual diagram of a display device according to the first and second embodiments.

FIG. 11 is a conceptual diagram showing how a semiconductor light emitting device is assembled in a display device according to the first and second embodiments.

FIG. 12 is a cross-sectional view of a substrate structure for transferring a semiconductor light emitting device for pixels and a display device including the same according to the third embodiment.

FIG. 13 is a cross-sectional view of a substrate structure for transferring a semiconductor light emitting device for pixels and a display device including the same according to the fourth embodiment.

FIG. 14 is a conceptual diagram of a display device according to the third and fourth embodiments.

FIG. 15 is a conceptual diagram showing how a semiconductor light emitting device is assembled in a display device according to the third and fourth embodiments.

FIG. 16 is a plan view showing the arrangement of pores in a partition wall according to the fifth embodiment.

FIG. 17 is a plan view showing the arrangement of pores in a partition wall according to the sixth embodiment.

FIG. 18 is a plan view showing the arrangement of pores in a partition wall according to the seventh embodiment.

FIG. 19 is a plan view showing the arrangement of pores in a partition wall according to the eighth embodiment.

FIG. 20 is a conceptual diagram showing shrinkage according to the area of the substrate.

### MODE FOR INVENTION

Hereinafter, the embodiment disclosed in this specification will be described in detail with reference to the attached drawings. The suffixes ‘module’ and ‘part’ for elements used in the following description are given or used interchangeably in consideration of ease of specification preparation, and do not have distinct meanings or roles in themselves. Additionally, the attached drawings are intended to facilitate easy understanding of the embodiments disclosed in this specification, and the technical idea disclosed in this specification is not limited by the attached drawings. Additionally, when an element such as a layer, region or substrate is referred to as being ‘on’ another component, this includes either directly on the other element or there may be other intermediate elements in between.

Display devices described in this specification may include digital TVs, mobile phones, smart phones, laptop computers, digital broadcasting terminals, personal digital assistants (PDAs), portable multimedia players (PMPs), navigation, slate PCs, tablet PCs, ultra-books, desktop computers, etc. However, the configuration according to the embodiment described in this specification may be applied to a device capable of displaying even if it is a new product type that is developed in the future.

Hereinafter, a light emitting device according to an embodiment and a display device including the same will be described.

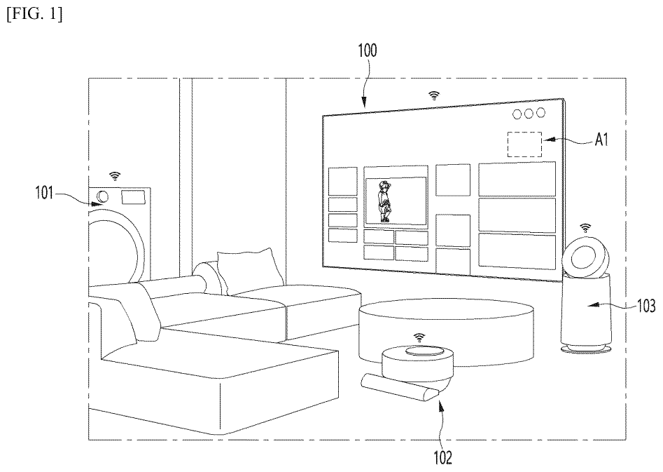

FIG. 1 shows a living room of a house where a display device 100 according to an embodiment is placed.

The display device 100 of the embodiment may display the status of various electronic products such as a washing machine 101, a robot vacuum cleaner 102, and an air purifier 103, and it is possible to communicate with each electronic product based on IOT and control each electronic product based on the user's setting data.

The display device 100 according to the embodiment may include a flexible display manufactured on a thin and flexible substrate. Flexible displays may bend or curl like paper while maintaining the characteristics of existing flat displays.

In a flexible display, visual information may be implemented by independently controlling the light emission of unit pixels arranged in a matrix form. A unit pixel refers to the minimum unit for implementing one color. A unit pixel of a flexible display may be implemented by a light emitting device. In the embodiment, the light emitting device may be Micro-LED or Nano-LED, but is not limited thereto.

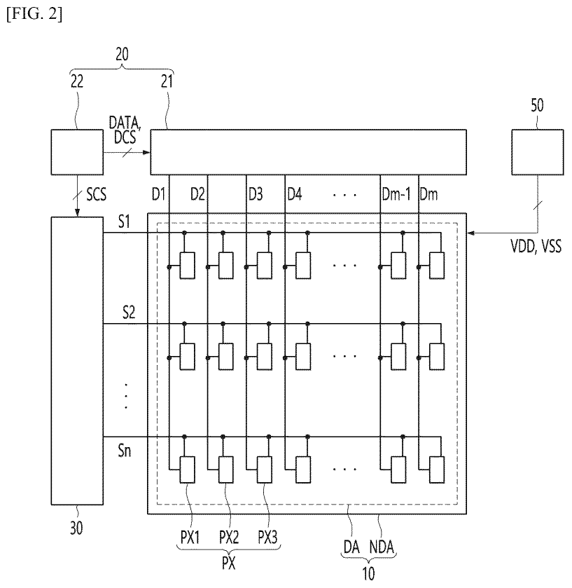

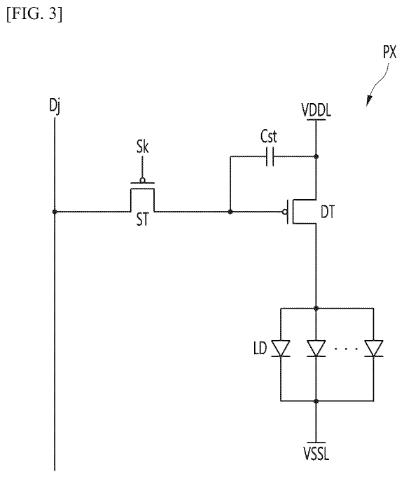

FIG. 2 is a block diagram schematically showing a display device according to the embodiment, and FIG. 3 is a circuit diagram showing an example of the pixel of FIG. 2.

Referring to FIGS. 2 and 3, a display device according to an embodiment may include a display panel 10, a driving circuit 20, a scan driver 30, and a power supply circuit 50.

The display device 100 of the embodiment may drive the light emitting device in an active matrix (AM) method or a passive matrix (PM) method.

The driving circuit 20 may include a data driver 21 and a timing control unit 22.

The display panel 10 may be divided into a display area DA and a non-display area NDA disposed around the display area DA. The display area DA is an area where pixels PX are formed to display an image. The display panel 10 may include a data lines (D1 to Dm, m is an integer greater than 2), a scan lines (S1 to Sn, n is an integer greater than 2) that intersect the data lines D1 to Dm, and a high-potential voltage line supplied with a high-potential voltage,

Each of the pixels PX may include a first sub-pixel PX1, a second sub-pixel PX2, and a third sub-pixel PX3. The first sub-pixel PXT may emit the first color light of the first wavelength, the second sub-pixel PX2 may emit the second color light of the second wavelength, and the third sub-pixel PX3 may emit the third color light of the third wavelength. The first color light may be red light, the second color light may be green light, and the third color light may be blue light, but are not limited thereto. Additionally, in FIG. 2, it is illustrated that each of the pixels PX may include three sub-pixels, but the present invention is not limited thereto. That is, each pixel PX may include four or more sub-pixels.

Each of the first sub-pixel PX1, the second sub-pixel PX2, and the third sub-pixel PX3 may be connected to at least one of the data lines D1 to Dm and at least one of the scan lines S1 to Sn and a high-potential voltage liens. As shown in FIG. 3, the first sub-pixel PXT may include light emitting devices LD, a plurality of transistors for supplying current to the light emitting devices LD, and at least one capacitor Cst.

Although not shown in the drawing, each of the first sub-pixel PXT, the second sub-pixel PX2, and the third sub-pixel PX3 may include only one light emitting device LD and at least one capacitor Cst.

Each of the light emitting devices LD may be a semiconductor light emitting diode including a first electrode, a plurality of conductivity type semiconductor layers, and a second electrode. Here, the first electrode may be an anode electrode and the second electrode may be a cathode electrode, but this is not limited.

Referring to FIG. 3, the plurality of transistors may include a driving transistor DT that supplies current to the light emitting devices LD, a scan transistor ST that supplies a data voltage to the gate electrode of the driving transistor DT. The driving transistor DT may include a gate electrode connected to the source electrode of the scan transistor ST, a source electrode connected to a high-potential voltage line to which a high-potential voltage is applied and a drain electrode connected to the first electrodes of the light emitting devices LD. The scan transistor ST may include a gate electrode connected to the scan line (Sk, k is an integer that satisfies 1≤k≤n), a source electrode connected to the gate electrode of the driving transistor DT, and a drain electrode connected to the data line (Dj, j is an integer that satisfies 1≤j≤m).

The capacitor Cst is formed between the gate electrode and the source electrode of the driving transistor DT. The storage capacitor Cst may charge the difference between the gate voltage and the source voltage of the driving transistor DT.

The driving transistor DT and the scan transistor ST may be formed of a thin film transistor. In addition, in FIG. 3, the driving transistor DT and the scan transistor ST are mainly described as being formed of a P-type MOSFET (Metal Oxide Semiconductor Field Effect Transistor), but the present invention is not limited thereto. The driving transistor DT and scan transistor ST may be formed of an N-type MOSFET. In this case, the positions of the source and drain electrodes of the driving transistor DT and the scan transistor ST may be changed.

In addition, Although FIG. 3 illustrates that each of the first sub-pixel PX1, the second sub-pixel PX2, and the third sub-pixel PX3 includes a 2T1C (2 Transistor-1 capacitor) having one driving transistor DT, one scan transistor ST, and one capacitor Cst, the present invention is not limited thereto. Each of the first sub-pixel PX1, the second sub-pixel PX2, and the third sub-pixel PX3 may include a plurality of scan transistors ST and a plurality of capacitors Cst.

Referring again to FIG. 2, the driving circuit 20 outputs signals and voltages for driving the display panel 10. For this purpose, the driving circuit 20 may include a data driver 21 and a timing controller 22.

The data driver 21 receives digital video data DATA and source control signal DCS from the timing control unit 22. The data driver 21 convert digital video data DATA into analog data voltages according to the source control signal DCS and supplies them to the data lines D1 to Dm of the display panel 10.

The timing control unit 22 receives digital video data DATA and timing signals from the host system. Timing signals may include a vertical sync signal, a horizontal sync signal, a data enable signal, and a dot clock. The host system may be an application processor in a smartphone or tablet PC, a monitor, or a system-on-chip in a TV.

The scan driver 30 receives a scan control signal SCS from the timing control unit 22. The scan driver 30 generates scan signals according to the scan control signal SCS and supplies them to the scan lines S1 to Sn of the display panel 10. The scan driver 30 may include a plurality of transistors and may be formed in the non-display area NDA of the display panel 10. Alternatively, the scan driver 30 may be formed as an integrated circuit, and in this case, it may be mounted on a gate flexible film attached to the other side of the display panel 10.

The power supply circuit 50 may generate a high-potential voltage VDD and a low-potential voltage VSS for driving the light emitting devices (LD) of the display panel 10 from the main power supply and supply them to the high-potential voltage line and the low-potential voltage line of the display panel 10. Additionally, the power supply circuit 50 may generate and supply driving voltages for driving the driving circuit 20 and the scan driver 30 from the main power supply.

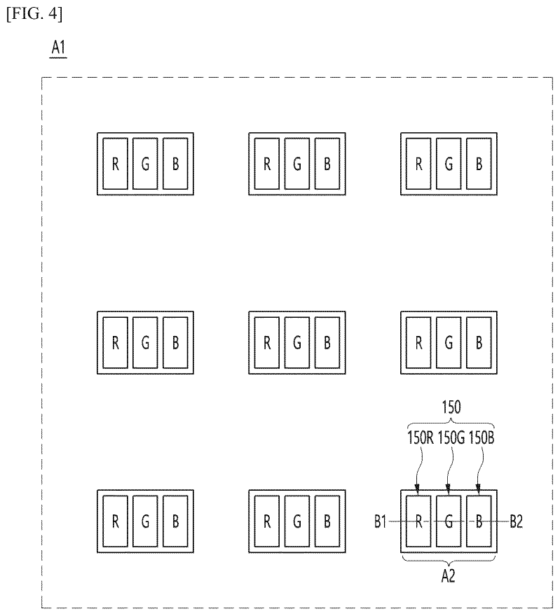

FIG. 4 is an enlarged view of the first panel area A1 in the display device of FIG. 1.

According to FIG. 4, the display device 100 of the embodiment may be manufactured by mechanically and electrically connecting a plurality of panel areas, such as the first panel area A1, by tiling.

The first panel area A1 may include a plurality of light emitting devices 150 arranged for each unit pixel (PX in FIG. 2).

For example, the unit pixel PX may include a first sub-pixel PX1, a second sub-pixel PX2, and a third sub-pixel PX3. For example, a plurality of red light emitting devices 150R are disposed in the first sub-pixel PX1, a plurality of green light emitting devices 150G are disposed in the second sub-pixel PX2, and a plurality of blue light emitting devices 150B may be placed in the third sub-pixel PX3. The unit pixel PX may further include a fourth sub-pixel in which no light emitting device is disposed, but this is not limited. Meanwhile, the light emitting device 150 may be a semiconductor light emitting device.

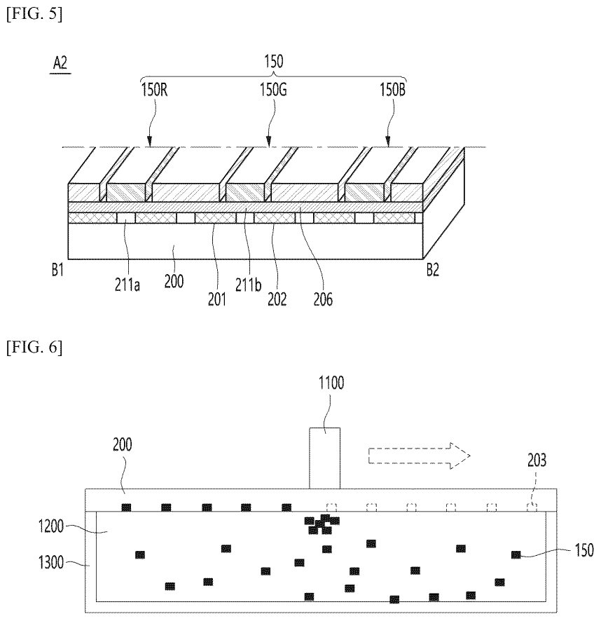

Next, FIG. 5 is a cross-sectional view taken along line B1-B2 in area A2 of FIG. 4.

Referring to FIG. 5, the display device 100 of the embodiment may include a substrate 200, assembly wiring 201 and 202, a first insulating layer 211a, a second insulating layer 211b, a third insulating layer 206 and a plurality of light emitting devices 150.

The assembly wiring may include a first assembly wiring 201 and a second assembly wiring 202 that are spaced apart from each other. The first assembly wiring 201 and the second assembly wiring 202 may be provided to generate dielectrophoretic force to assemble the light emitting device 150. Additionally, the first assembly wiring 201 and the second assembly wiring 202 may be electrically connected to the electrodes of the light emitting device and may function as electrodes of the display panel.

The assembly wirings 201 and 202 may be formed of transparent electrodes (ITO) or may contain a metal material with excellent electrical conductivity. For example, the assembly wirings 201 and 202 may be formed of at least one of titanium (Ti), chromium (Cr), nickel (Ni), aluminum (Al), platinum (Pt), gold (Au), tungsten (W), or molybdenum (Mo) or an alloy thereof.

The first insulating layer 211a may be disposed between the first assembly wiring 201 and the second assembly wiring 202, and the second insulating layer 211b may be disposed on the first assembly wiring 201 and the second assembly wiring 202. The first insulating layer 211a and the second insulating layer 211b may be an oxide film or a nitride film, but are not limited thereto.

The light emitting device 150 may include, but is not limited to, a red light emitting device 150, a green light emitting device 150G, and a blue light emitting device 150B0 to form a sub-pixel, and it is also possible to implement red and green colors by using red phosphors and green phosphors, respectively.

The substrate 200 may be formed of glass or polyimide. Additionally, the substrate 200 may include a flexible material such as PEN (Polyethylene Naphthalate) or PET (Polyethylene Terephthalate). Additionally, the substrate 200 may be made of a transparent material, but is not limited thereto.

The third insulating layer 206 may include an insulating and flexible material such as polyimide, PEN, PET, etc., and may be integrated with the substrate 200 to form one substrate.

The third insulating layer 206 may be a conductive adhesive layer that has adhesiveness and conductivity, and the conductive adhesive layer is flexible and may enable a flexible function of the display device. For example, the third insulating layer 206 may be an anisotropic conductive film (ACF) or a conductive adhesive layer such as an anisotropic conductive medium or a solution containing conductive particles. The conductive adhesive layer may be a layer that is electrically conductive in a direction perpendicular to the thickness, but electrically insulating in a direction horizontal to the thickness.

The third insulating layer 206 may include an assembly hole 203 into which the light emitting device 150 is inserted (see FIG. 6). Therefore, during self-assembly, the light emitting device 150 may be easily inserted into the assembly hole 203 of the third insulating layer 206. The assembly hole 203 may be called an insertion hole, a fixing hole, an alignment hole, etc.

The gap between the assembly wires 201 and 202 is formed to be smaller than the width of the light emitting device 150 and the width of the assembly hole 203, so that the assembly position of the light emitting device 150 using an electric field may be fixed more precisely.

A third insulating layer 206 is formed on the assembly wirings 201 and 202 to protect the assembly wirings 201 and 202 from the fluid 1200 and leakage of current flowing through the assembly wiring 201 and 202 may be prevented. The third insulating layer 206 may be formed as a single layer or multilayer of an inorganic insulator such as silica or alumina or an organic insulator.

Additionally, the third insulating layer 206 may include an insulating and flexible material such as polyimide, PEN, PET, etc., and may be integrated with the substrate 200 to form one substrate.

The third insulating layer 206 may be an adhesive insulating layer or a conductive adhesive layer with conductivity. The third insulating layer 206 is flexible and may enable a flexible function of the display device.

The third insulating layer 206 has a partition wall, and the assembly hole 203 may be formed by the partition wall. For example, when forming the substrate 200, a portion of the third insulating layer 206 is removed, so that each of the light emitting devices 150 may be assembled into the assembly hole 203 of the third insulating layer 206.

An assembly hole 203 where the light emitting devices 150 are coupled is formed in the substrate 200, and the surface where the assembly hole 203 is formed may be in contact with the fluid 1200. The assembly hole 203 may guide the exact assembly position of the light emitting device 150.

Meanwhile, the assembly hole 203 may have a shape and size corresponding to the shape of the light emitting device 150 to be assembled at the corresponding location. Accordingly, it is possible to prevent another light emitting device from being assembled in the assembly hole 203 or a plurality of light emitting devices from being assembled.

FIG. 6 is a diagram showing an example in which a light emitting device according to an embodiment is assembled to a substrate by a self-assembly method, and the self-assembly method of the light emitting device is explained with reference to the drawings.

The substrate 200 may be a panel substrate of a display device. In the following description, the substrate 200 will be described as a panel substrate of a display device, but the embodiment is not limited thereto.

Referring to FIG. 6, a plurality of light emitting devices 150 may be input into a chamber 1300 filled with a fluid 1200. The fluid 1200 may be water such as ultrapure water, but is not limited thereto. The chamber may be called a water tank, container, container, etc.

After this, the substrate 200 may be placed on the chamber 1300. Depending on the embodiment, the substrate 200 may be input into the chamber 1300.

As shown in FIG. 5, a pair of assembly wirings 201 and 202 corresponding to each of the light emitting devices 150 to be assembled may be disposed on the substrate 200.

Referring to FIG. 6, after the substrate 200 is disposed, the assembly device 1100 including a magnetic material may move along the substrate 200. For example, a magnet or electromagnet may be used as a magnetic material. The assembly device 1100 may move while in contact with the substrate 200 in order to maximize the area to which the magnetic field is applied within the fluid 1200. Depending on the embodiment, the assembly device 1100 may include a plurality of magnetic materials or a magnetic material of a size corresponding to that of the substrate 200. In this case, the moving distance of the assembly device 1100 may be limited to within a predetermined range.

By the magnetic field generated by the assembly device 1100, the light emitting device 150 in the chamber 1300 may move toward the assembly device 1100.

While moving toward the assembly device 1100, the light emitting device 150 may enter the assembly hole 203 and contact the substrate 200 by a dielectrophoretic force (DEP force).

Specifically, The assembly wirings 201 and 202 form an electric field by an externally supplied power source, and a dielectrophoretic force may be formed between the assembly wirings 201 and 202 by this electric field. The light emitting device 150 may be fixed to the assembly hole 203 on the substrate 200 by this dielectrophoretic force.

An electric field applied by the assembly wiring 201 and 202 formed on the substrate 200 may be prevented from being separated by movement of the assembly device 1100 by the electric field applied by the assembly wiring 201 and 202 formed on the substrate. It According to the embodiment, by using the above-described self-assembly method using an electromagnetic field, the time required to assemble each of the light emitting devices 150 on the substrate 200 may be drastically shortened, so that a large-area, high-pixel display may be implemented more quickly and economically.

At this time, a predetermined solder layer (not shown) is formed between the light emitting device 150 assembled on the assembly hole 203 of the substrate 200 and the assembly electrode, thereby improving the bonding strength of the light emitting device 150.

Next, a molding layer (not shown) may be formed in the assembly hole 203 of the substrate 200. The molding layer may be a transparent resin or a resin containing a reflective material or a scattering material.

Hereinafter, an embodiment for preventing bending of the substrate during self-assembly will be described.

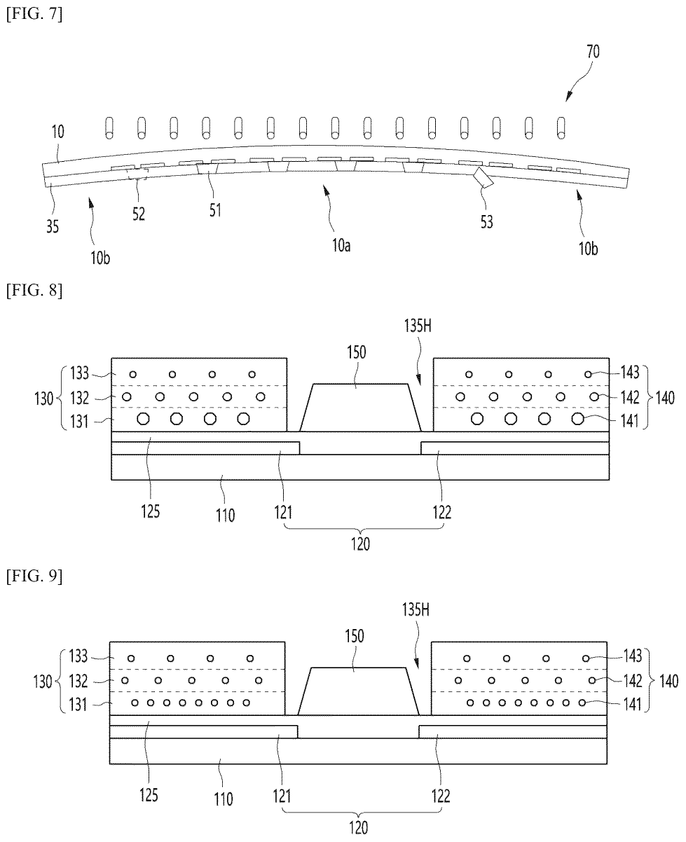

FIG. 7 is a conceptual diagram showing a defective issue at the panel stage in an undisclosed internal semiconductor light emitting device. Referring to FIG. 7, a magnet array 70 is disposed on the display panel. The display panel may include a substrate 10, an insulating layer 35, assembly wiring, and a semiconductor light emitting device. Semiconductor light emitting devices may be self-assembled into a display panel by the magnetic force of the magnet array 70 in the fluid.

However, as the display panel substrate becomes larger and deposition and patterns are formed in multiple layers, the weight of the substrate increases, and bending in an unspecified direction may occur due to stress and tension within the substrate. The substrate 10 may include a central portion 10a and an edge portion 10b, and the heights of the central portion 10a and the edge portion 10b may be different due to gravity.

Accordingly, a problem may occur in which the gap between the substrate 10 and the magnet array 70 is uneven, which may cause a problem in which the semiconductor light emitting device is not properly assembled in the assembly hole of the display panel substrate.

Semiconductor light emitting device may include a first semiconductor light emitting device (51) that is assembled, an unassembled second semiconductor light emitting device 52, and a tilted third semiconductor light emitting device 53. Thus, there is an issue of deterioration in the performance of the display device due to non-assembly or incorrect assembly.

Therefore, a method for preventing bending of the substrate, improving the assembly rate, and improving the performance of the display device will be explained through the following examples.

The embodiments described in FIGS. 8 to 11 may correspond when the self-assembly method of the display device is the face-down assembly method.

FIG. 8 is a conceptual diagram of a substrate structure for transfer of a semiconductor light emitting device for pixels according to the first embodiment. Referring to FIG. 8, The first embodiment may include a plurality of assembly wiring 120 disposed on the substrate, an insulating film 125 disposed on the plurality of assembly wirings 120, and a partition wall is placed on the insulating film and has an assembly hole 135H. A semiconductor light emitting device 150 may be placed in the assembly hole 135H.

The plurality of assembly wirings 120 may include first assembly wiring 121 and second assembly wiring 122 arranged to be spaced apart from each other. The first assembly wiring 221 and the second assembly wiring 222 are supplied with different power sources through alternating current, forming a DEP force so that the semiconductor light emitting device 150 may be assembled into the assembly hole 135H.

Meanwhile, the partition wall 130 may include a porous structure. A pore 140 is disposed within the partition wall 130, and the pore may include a first hole 141, a second hole 142, and a third hole 143 that are regularly arranged. Additionally, the partition wall 130 may include a first area 131, a second area 132, and a third area 133 based on the height from the substrate 110. The first, second, and third areas 131, 132, and 133 may be formed as a single layer or may be formed as a plurality of layers. The diameter of the pore 140 may range from about 100 nm to 3 μm, but is not limited thereto.

Meanwhile, as the partition wall 130 has fewer pores and the amount of material forming the partition wall 130 increases, shrinkage due to heat may decrease. Accordingly, the first embodiment has the technical effect of controlling thermal expansion and contraction of the partition wall 130 by forming a pore 140 in the partition wall 130.

In the first embodiment, a first hole 141 is disposed in the first area 131, a second hole 142 is disposed in the second area 132, and a third hole 143 may be disposed in the third area 133. Additionally, each of the first, second, and third holes 141, 142, and 143 may have a volume of 5 to 20% of the volume of the partition wall 130, but is not limited thereto.

Meanwhile, the pores 140 existing within the partition wall 130 may have different shapes depending on the area within the partition wall 130. In detail, the size of the first hole 141 may be larger than the size of the second hole 142. Additionally, the size of the second hole 142 may be larger than the size of the third hole 143. Additionally, the number of first, second, and third holes 141, 142, and 143 may be similar.

Accordingly, the closer the partition wall 130 is to the substrate 110 in the vertical direction, the higher the density of pores 140 may be.

Therefore, as the substrate structure for transfer of the semiconductor light emitting device for pixels according to the first embodiment the closer it is to the substrate in the vertical direction, the higher the density of pores 140 becomes, and the closer it is to the substrate 100, the lower the density of the pores 140 may be. Accordingly, in the first embodiment, the first area 131 of the partition wall 130 may experience little shrinkage, and the third area 133 may experience relatively large shrinkage.

Accordingly, because shrinkage occurs in the third region 133 of the partition wall 130, which is far from the substrate 110, the center of the substrate 110 may be concave downward.

Accordingly, in the first embodiment, as the central portion of the substrate 110 is concave downward compared to the edge portion, when assembling face-down, the phenomenon of the central portion of the substrate 110 being convex downward due to gravity is offset, so that the substrate 110 may prevent bending. In addition, the bending phenomenon of the substrate 110 is prevented and the assembled magnets are maintained at a constant distance between the center and the edges of the substrate 110, which has the technical effect of improving the assembly rate. Meanwhile, the partition wall 130 includes a porous structure, and pores 140 also exist on the surface of the partition wall 130, which may be formed as a concavo-convex structure. Accordingly, due to the hole existing on the surface of the partition wall 130 during self-assembly, the semiconductor light emitting device dispersed in the fluid is not adsorbed to the partition wall 130 and may be placed in the assembly hole 135H.

In addition, after the semiconductor light emitting device 150 is assembled in the assembly hole 135H, the display process proceeds, and there is a technical effect of increasing the adhesion of a metal film, an organic film, an insulating film, etc. during a deposition process due to the pores 140 existing on the surface of the partition wall 130.

FIG. 9 is a conceptual diagram of a substrate structure for transfer of a semiconductor light emitting device for pixels according to the second embodiment. The second embodiment may adopt the technical features of the first embodiment. For example, a pore 140 is disposed within the partition wall 130, and the embodiment has the technical effect of preventing bending of the substrate through the pores 140.

In the second embodiment, the partition wall 130 may include a first area 131, a second area 132, and a third area 133 depending on the height from the substrate 110. At this time, the density of pores in the first, second, and third areas (131, 132, and 133) may be different. In detail, the density of the pores 140 in the first area 131 may be greater than the density of the pores 140 in the second area 132. Additionally, the density of the pores 140 in the second area 132 may be greater than the density of the pores 140 in the third area 133.

The pores 140 may be formed to have similar sizes, and there may be differences in the number of pores 140 in the first, second, and third areas (131, 132, and 133). The number of pores 140 in the first area 131 may be greater than the number of pores 140 in the second area 132. Additionally, the number of pores 140 in the second area 132 may be greater than the number of pores 140 in the third area 133.

In the second embodiment, the density of the pores 140 within the partition wall 130 may be greater as they approach the substrate 110, and when the pores 140 have similar sizes, the closer to the substrate 110 the greater the number of pores 140 may be.

Accordingly, in the second embodiment, the first area 131 of the partition wall 130 has a higher density of pores 140 than the third area 133, so the closer it is to the substrate 110, the less shrinkage occurs, and shrinkage may increase as the distance from the substrate 110 increases.

Therefore, because shrinkage occurs in the third area 133 of the partition wall 130, which is far from the substrate 110, the center of the substrate 110 may be concave downward.

Accordingly, the second embodiment has the technical effect of preventing bending of the substrate 110, as the central portion of the substrate 110 becomes concave lower than the edge portion, the phenomenon of the central portion of the substrate 110 becoming convex downward due to gravity during face-down assembly is offset. In addition, the bending phenomenon of the substrate 110 is prevented and the assembled magnets are maintained at a constant distance between the center and the edges of the substrate 110, which has the technical effect of improving the assembly rate.

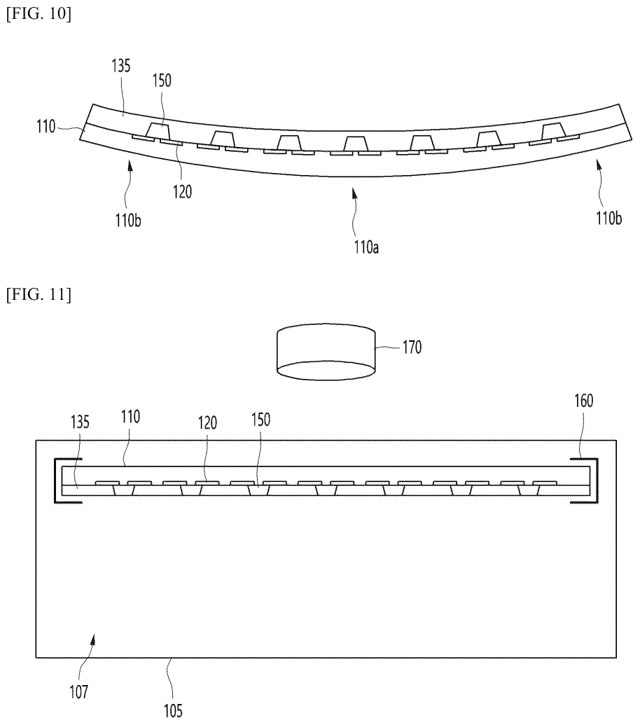

FIG. 10 is a conceptual diagram showing the shrinkage of the substrate in the substrate structure for transfer of the semiconductor light emitting device for pixels according to the first and second embodiments. Referring to FIG. 10, the partition wall 130 present in the insulating layer 135 includes a porous structure, and shrinkage of the substrate may be controlled depending on the arrangement of the pores.

In the first and second embodiments, the closer the insulating layer 135 is to the substrate 110 in the vertical direction, the larger the density of pores is, and the farther it is from the substrate 110, the smaller the density of pores is. Accordingly, the insulating layer 135 shrinks in areas where the density of pores is low, and the insulating layer 135 and the substrate 110 may have a downwardly concave shape.

Accordingly, the substrate structure for transfer of the semiconductor light emitting device for pixels according to the first and second embodiments has the technical effect of preventing bending of the substrate by offsetting gravity through a concave downward substrate When self-assembling using the face-down method.

FIG. 11 is a conceptual diagram showing how a semiconductor light emitting device is assembled in a face-down manner in a display device according to the first and second embodiments. Referring to FIG. 11, the water tank 105 is filled with a fluid 107, and the substrate 110 may be fixed in the fluid 107 by the substrate support 160. An assembly magnet 170 is disposed on the substrate 110, and the semiconductor light emitting device 150 may be pulled to the substrate 110 by the assembly magnet 170.

Meanwhile, in an undisclosed internal technology, the problem of the edge portion of the substrate 110 being supported by the substrate support 160 and the central portion of the substrate being convex downward due to gravity was studied.

On the other hand, in the substrate structure for transfer of the semiconductor light emitting device for pixels according to the first and second embodiments, the partition wall within the insulating layer 135 contains pores, as the density of pores is higher in an area closer to the substrate 110 than in an area far from the substrate 110, the insulating layer 135 and the substrate 110 may be concave downward.

Therefore, when self-assembly is performed using the face-down method, the assembled substrate structures of the first and second embodiments are inverted by 180 degrees and may be positioned in a convex upward state.

At this time, the phenomenon of the central part being attracted in the direction of gravity due to gravity is offset by the upwardly convex substrate 110 formed by the porous partition wall, which has the technical effect of preventing the substrate 110 from bending.

In addition, the substrate self-assembles in a flat form, and the distance from the assembly magnet 170 is maintained constant regardless of the area of the substrate 110, which has the technical effect of increasing the assembly rate.

Meanwhile, when the substrate 110 is immersed in the fluid 107, one end of the substrate 110 may be immersed first and then the other end.

In this case, the insulating layer 135 adjacent to one end of the substrate 110 that is submerged first may have a lower density of pores than the insulating layer 135 adjacent to the other end. In detail, depending on the order in which the substrate 110 is immersed in the fluid 107, the area of the substrate 110 that is immersed first may have a smaller density of pores.

Accordingly, one end of the substrate 110 that is first immersed in the fluid 107 may minimize the generation of tension compared to the other end of the substrate 110 that is immersed later, and the prevention of bending of the substrate may be further improved.

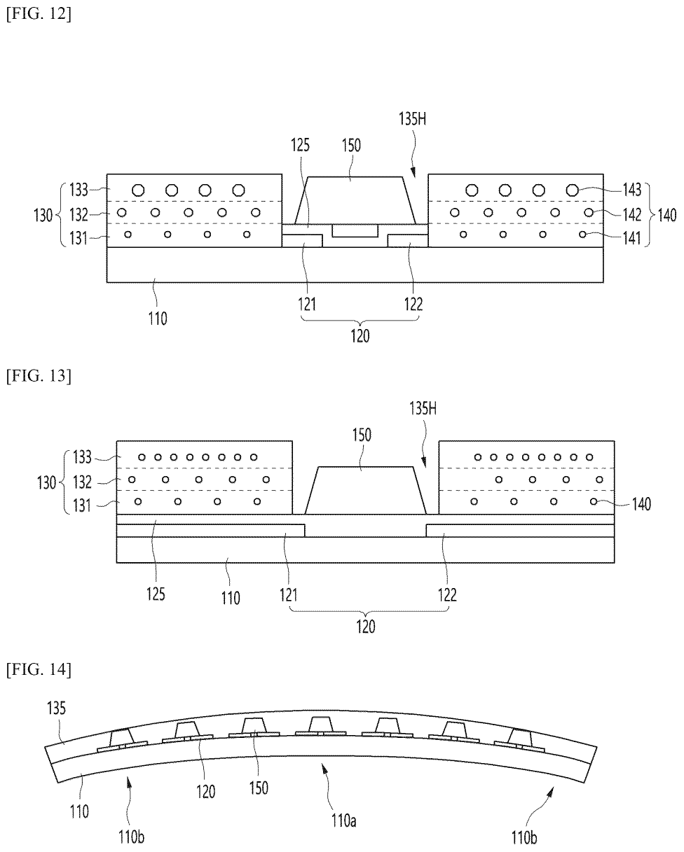

Next, the embodiments described in FIGS. 12 to 15 may correspond when the self-assembly method of the display device is the face-up method. FIG. 12 is a cross-sectional view of a substrate structure for transfer of a semiconductor light emitting device for pixels according to a third embodiment. The third embodiment may adopt the technical features of the first and second embodiments. For example, in the third embodiment, the partition wall 130 includes a porous structure, which has the technical effect of preventing warping of the substrate.

Referring to FIG. 12, the partition wall 130 may include a first area 131, a second area 132, and a third area 133 based on the height from the substrate 110. The first, second, and third areas 131, 132, and 133 may be formed as a single layer or may be formed as a plurality of layers. The diameter of the pore 140 may range from about 100 nm to 3 μm, but is not limited thereto.

In the third embodiment, a first hole 141 is disposed in the first area 131, a second hole 142 is disposed in the second area 132, and a third hole 143 may be placed in the third area 133. Additionally, each of the first, second, and third holes 141, 142, and 143 may have a volume of 5 to 20% of the volume of the partition wall 130, but is not limited thereto.

Meanwhile, the pores 140 existing within the partition wall 130 may have different shapes depending on the area within the partition wall 130. In detail, the size of the first hole 141 may be smaller than the size of the second hole 142. Additionally, the size of the second hole 142 may be smaller than the size of the third hole 143. Additionally, the number of first, second, and third holes 141, 142, and 143 may be similar.

Accordingly, the density of the pores 140 within the partition wall 130 may be smaller as they are closer to the substrate 110 in the vertical direction. Additionally, if the density of the pores 140 decreases, the shrinkage of the partition wall 130 may increase compared to an area with a large density of pores.

Therefore, in the third embodiment, the first area 131 of the partition wall 130 may have relatively high shrinkage, and the third area 133 may have relatively low shrinkage. Subsequently, because shrinkage occurs in the first area 131 of the partition wall 130 close to the substrate 110, the center of the substrate 110 may be convex upward.

Accordingly, the third embodiment has the technical effect of preventing bending of the substrate 110, as the central portion of the substrate 110 becomes more convex than the edge portion, by offsetting the downward attraction of the central part of the substrate 110 due to gravity when assembling the face-up method.

In addition, the partition wall 130 includes a porous structure, and pores 140 also exist on the surface of the partition wall 130, which may be formed as a concavo-convex structure. Accordingly, due to the hole existing on the surface of the partition wall 130 during self-assembly, the semiconductor light emitting device dispersed in the fluid is not adsorbed to the partition wall 130 and may be placed in the assembly hole 135H.

In addition, after the semiconductor light emitting device 150 is assembled in the assembly hole 135H, the display process proceeds. There is a technical effect of increasing the adhesion of a metal film, an organic film, an insulating film, etc. during a deposition process due to the pores 140 existing on the surface of the partition wall 130.

FIG. 13 is a cross-sectional view of a substrate structure for transfer of a semiconductor light emitting device for pixels according to the fourth embodiment. The fourth embodiment may adopt the technical features of the first, second, and third embodiments. For example, in the fourth embodiment, the partition wall 130 includes a porous structure, which has the technical effect of preventing warping of the substrate.

In the fourth embodiment, the partition wall 130 may include a first area 131, a second area 132, and a third area 133 depending on the height from the substrate 110. At this time, the density of pores in the first, second, and third areas (131, 132, and 133) may be different. In detail, the density of the pores 140 in the first area 131 may be smaller than the density of the pores 140 in the second area 132. Additionally, the density of the pores 140 in the second area 132 may be less than the density of the pores 140 in the third area 133.

The pores 140 may be formed to have similar sizes, and there may be differences in the number of pores 140 in the first, second, and third areas (131, 132, and 133). The number of pores 140 in the first area 131 may be less than the number of pores 140 in the second area 132. Additionally, the number of pores 140 in the second area 132 may be less than the number of pores 140 in the third area 133.

In the fourth embodiment, the density of the pores 140 within the partition wall 130 may be lower as they are closer to the substrate 110, if the pores 140 have similar sizes, the closer to the substrate 110 the smaller the number of pores 140 may be.

Accordingly, in the fourth embodiment, the first area 131 of the partition wall 130 has a lower density of pores 140 than the third area 133, so the closer it is to the substrate 110, the more shrinkage occurs and as the distance from the substrate 110 increases, shrinkage may decrease. Because shrinkage occurs in the first area 131 of the partition wall 130 close to the substrate 110, the central portion of the substrate 110 may have a convex upward shape.

Therefore, the fourth embodiment as the central portion of the substrate 110 becomes more convex than the edge portion, the phenomenon of the central portion of the substrate 110 being pulled downward by gravity during face-up assembly may be offset and has the technical effect of preventing bending of the substrate 110.

In addition, the bending phenomenon of the substrate 110 is prevented and the assembled magnets are maintained at a constant distance between the center and the edges of the substrate 110, which has the technical effect of improving the assembly rate.

FIG. 14 is a conceptual diagram showing the shrinkage of the substrate in the substrate structure for transfer of the semiconductor light emitting device for pixels according to the third and fourth embodiments. Referring to FIG. 14, the partition wall 130 present in the insulating layer 135 includes a porous structure, and shrinkage of the substrate may be controlled depending on the arrangement of the pores.

In the third and fourth embodiments, the closer the insulating layer 135 is to the substrate 110 in the vertical direction, the smaller the density of pores is, and the farther it is from the substrate 110, the larger the density of pores is. Accordingly, the insulating layer 135 shrinks in a region where the density of pores is small, and the insulating layer 135 and the substrate 110 may have a shape that is convex upward.

Accordingly, the substrate structure for the transfer of the semiconductor light emitting device for pixels according to the third and fourth embodiments is a face-up method, which has the technical effect of preventing substrate bending by offsetting gravity through the upwardly convex substrate during self-assembly.

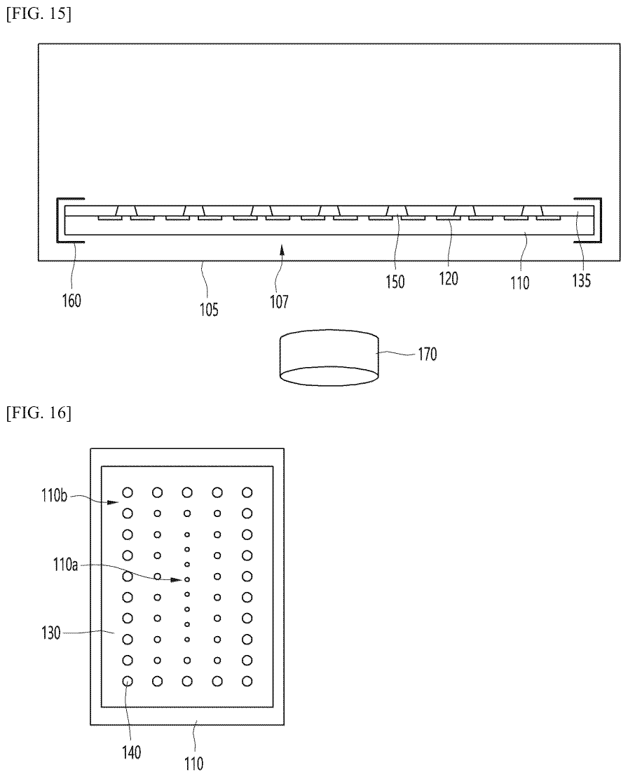

FIG. 15 is a conceptual diagram showing how a semiconductor light emitting device is assembled in a face-up method in a display device according to the third and fourth embodiments. Referring to FIG. 15, the water tank 105 is filled with a fluid 107, and the substrate 110 may be fixed in the fluid 107 by the substrate support 160. An assembly magnet is disposed under the substrate 110, and the semiconductor light emitting device 150 may be pulled to the substrate 110 by the assembly magnet 170.

Meanwhile, in an undisclosed internal technology, the problem of the edge portion of the substrate 110 being supported by the substrate support 160 and the central portion of the substrate being concave downward due to gravity was studied.

On the other hand, in the substrate structure for transfer of the semiconductor light emitting device for pixels according to the third and fourth embodiments, the partition wall within the insulating layer 135 contains pores, as the density of pores is higher in an area far from the substrate 110 than in an area close to the substrate 110, the insulating layer 135 and the substrate 110 may be convex upward.

Therefore, when self-assembly is performed using the face-up method, the phenomenon in which the central part of the substrate 110 is attracted in the direction of gravity due to gravity is offset by the upwardly convex substrate 110 formed by the porous partition wall, thereby preventing the substrate 110 from bending. In addition, the substrate is self-assembled in a flat shape, and the distance from the assembly magnet 170 is maintained constant regardless of the area of the substrate 110, which has the technical effect of increasing the assembly rate.

Meanwhile, when the substrate 110 is immersed in the fluid 107, one end of the substrate 110 may be immersed first and then the other end.

In this case, the insulating layer 135 adjacent to one end of the substrate 110 that is submerged first may have a lower density of pores than the insulating layer 135 adjacent to the other end. In detail, depending on the order in which the substrate 110 is immersed in the fluid 107, the area of the substrate 110 that is immersed first may have a smaller density of pores.

Accordingly, one end of the substrate 110 that is first immersed in the fluid 107 may minimize the generation of tension compared to the other end of the substrate 110 that is immersed later, and there is a technical effect that may further improve the prevention of bending of the substrate.

FIG. 16 is a plan view of a substrate on which a porous partition wall is formed according to the fifth embodiment. Referring to FIG. 16, a partition wall 130 is disposed on the substrate 110, and the partition wall 130 may include a porous structure. Additionally, the size of the pore 140 in the central portion 110a may be smaller than the size of the pore 140 in the edge portion 110b. Accordingly, in the fifth embodiment, the density of the pores 140 at the center 110a and the edge 110b of the substrate 110 may be different. In detail, the density of pores 140 in the central portion 110a may be smaller than the density of pores in the edge portion 110b.

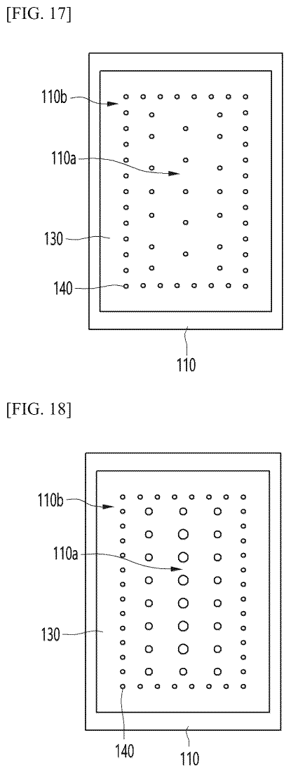

FIG. 17 is a plan view of a substrate on which a porous partition wall is formed according to the sixth embodiment. Referring to FIG. 17, a partition wall 130 is disposed on the substrate 110, and the partition wall 130 may include a porous structure. The sizes of the pores 140 may be similar, and the number of pores 140 in the central portion 110a may be smaller than the number of pores in the edge portion 110b. Accordingly, in the sixth embodiment, the density of the pores 140 at the center 110a and the edge 110b of the substrate 110 may be different. In detail, the density of pores 140 in the central portion 110a may be smaller than the density of pores in the edge portion 110b.

Referring to FIG. 20 for a moment, if the density of pores 140 in the central portion 110a of the substrate 110 is low, shrinkage may increase in the central portion 110a. On the other hand, when the density of pores 140 at the edge portion 110b is relatively high, shrinkage at the edge portion 110b may be reduced. Accordingly, in the fifth and sixth embodiments, the center portion 110a of the substrate shrinks more than the edge portion 110b, so that the substrate 110 may have a downwardly concave shape. Accordingly, when self-assembly proceeds in the face-down method, there is a technical effect of preventing bending of the substrate by offsetting gravity.

Next, FIG. 18 is a plan view of a substrate on which a porous partition wall is formed according to the seventh embodiment. Referring to FIG. 18, a partition wall 130 is disposed on the substrate 110, and the partition wall 130 may include a porous structure. Additionally, the size of the pore 140 in the central portion 110a may be larger than the size of the pore 140 in the edge portion 110b. Accordingly, in the seventh embodiment, the density of the pores 140 at the center 110a and the edge 110b of the substrate 110 may be different. In detail, the density of pores 140 in the central portion 110a may be greater than the density of pores in the edge portion 110b.

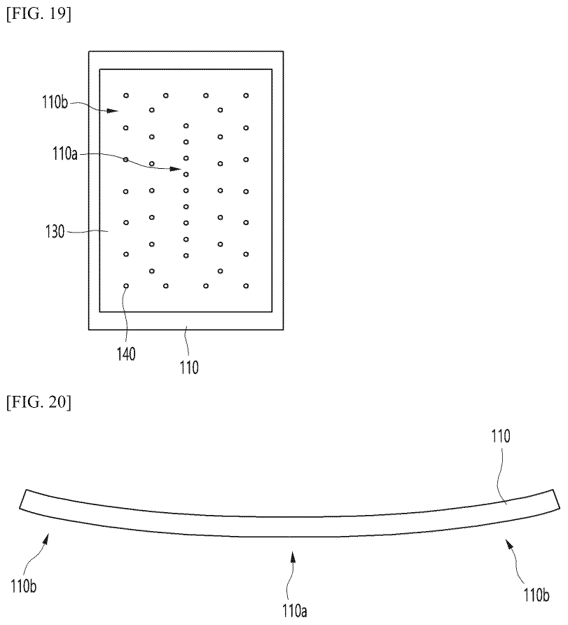

FIG. 19 is a plan view of a substrate on which a porous partition wall is formed according to the eighth embodiment. Referring to FIG. 19, a partition wall 130 is disposed on the substrate 110, and the partition wall 130 may include a porous structure. The sizes of the pores 140 may be similar, and the number of pores 140 in the central portion 110a may be greater than the number of pores in the edge portion 110b. Accordingly, in the eighth embodiment, the density of the pores 140 at the center 110a and the edge 110b of the substrate 110 may be different. In detail, the density of pores 140 in the central portion 110a may be greater than the density of pores in the edge portion 110b.

Referring to FIG. 20 for a moment, when the density of pores 140 in the central portion 110a of the substrate 110 is high, shrinkage may be reduced in the central portion 110a. On the other hand, if the density of pores 140 at the edge portion 110b is relatively high, shrinkage may increase at the edge portion 110b. Accordingly, in the seventh and eighth embodiments, the edge portion of the substrate 110b shrinks more than the center portion 110a, so that the substrate 110 may have an upwardly convex shape. Accordingly, when self-assembly is performed using the face-up method, there is a technical effect of preventing bending of the substrate by offsetting gravity.

According to an embodiment, when the substrate 110 is immersed in a fluid, one region of the substrate 110 may be immersed first and then the other region may be immersed. In this case, the insulating layer adjacent to one area of the substrate 110 that is submerged first may have a lower density of pores than the insulating layer adjacent to the other area. In detail, depending on the order in which the substrate 110 is immersed in the fluid, the area of the substrate 110 that is submerged first may have a smaller density of pores. Additionally, when the edge portion of the substrate is supported by the substrate support and the central portion of the substrate is pulled by gravity, the edge portion of the substrate may be immersed in the fluid before the central portion. In order to minimize the tension that occurs at this time, the density of pores may decrease from the insulating layer adjacent to the central portion of the substrate to the insulating layer adjacent to the edge portion of the substrate.

Accordingly, one area of the substrate 110 that is first immersed in the fluid may minimize the generation of tension compared to other areas of the substrate 110 that are immersed later, and there is a technical effect of further improving the prevention of bending of the substrate.

The semiconductor light emitting device for pixels and the display device including the same according to the embodiment have the technical effect of improving the assembly rate when assembling the semiconductor light emitting device to the panel substrate.

In addition, in the example, there is a technical effect of preventing substrate bending during face-down self-assembly.

For example, the embodiment may control the density of pores within the partition wall to prevent the bending of the substrate by offsetting the downward convexity of the central portion of the substrate due to gravity through substrate shrinkage.

In addition, in the embodiment, there is a technical effect of preventing bending of the substrate during face-up self-assembly.

For example, the embodiment may control the density of pores in the partition wall to prevent the bending of the substrate by offsetting the phenomenon in which the central portion of the substrate is concave downward due to gravity through substrate shrinkage.

Additionally, the embodiment has the technical effect of ensuring a uniform assembly rate regardless of area in a large-area substrate.

For example, since self-assembly proceeds in a flat form in the embodiment, the distance between the assembly magnet and the substrate is constant, so that a uniform assembly rate may be achieved regardless of the area of the substrate.

In addition, the embodiment has the technical effect of allowing the semiconductor light emitting device to be placed in the assembly hole without being adsorbed to the surface of the partition wall during self-assembly.

For example, a semiconductor light emitting device may not be adsorbed to the surface of a partition wall due to the concavo-convex structure formed by pores on the surface of the partition wall.

Additionally, in the embodiment, when the display process proceeds after the assembly process, there is a technical effect of increasing the adhesion of the deposition process.

For example, due to the concavo-convex structure formed by pores on the surface of the partition wall, adhesion may increase during the deposition process of metal films, organic films, and insulating films.

### EXPLANATION OF SIGNS

21: data driving unit
22: timing control unit
PX: pixels
PXT: first sub-pixel
PX2: second sub pixel
PX3: third sub-pixel
Cst: capacitor
DT: driving transistor
A1: first panel area
10, 110: substrate
10a, 110a: central part
10b, 110b: edge part
35, 135: insulating layer
50, 150: semiconductor light emitting device
51: first semiconductor light emitting device
52: second semiconductor light emitting device
53: third semiconductor light emitting device
70: magnet array
105: water tank
107: fluid
120: assembly wiring
121: first assembly wiring
122: second assembly wiring
125: insulating film
130: partition wall
131: first area
132: second area
133: third area
135H: assembly hole
140: porous
141: first hole
142: second hole
143: third hole
160: substrate support
170: assembly magnet

1. A substrate structure for transferring a semiconductor light emitting device for pixel, comprising:
a substrate having a plurality of assembly wirings; and
a partition wall disposed on the substrate and having an assembly hole into which a predetermined semiconductor light emitting device is assembled;
wherein the partition wall comprises a porous structure.

2. The substrate structure according to claim 1, wherein the partition wall comprises a first area disposed close to the substrate and a second area disposed far from the substrate, depending on the height from the substrate and
wherein a density of pores of the first area and a density of pores of the second area are different.

3. The substrate structure according to claim 2, wherein a size of pores in the first area is larger than a size of pores in the second area.

4. The substrate structure according to claim 2, wherein a number of pores in the first area is greater than a number of pores in the second area.

5. The substrate structure according to claim 2, a size of pores in the first area is smaller than a size of pores in the second area.

6. The substrate structure according to claim 2, wherein a number of pores in the first area is less than a number of pores in the second area.

7. The substrate structure according to claim 1, wherein a concavo-convex structure is formed on a surface of the partition wall due to the porous structure.

8. The substrate structure according to claim 1, wherein a density of pores adjacent to a central portion of the substrate is different from a density of pores adjacent to an edge portion of the substrate.

9. The substrate structure according to claim 8, wherein the density of pores adjacent to the central portion of the substrate is greater than the density of pores adjacent to the edge portion of the substrate.

10. The substrate structure according to claim 8, wherein the density of pores adjacent to the central portion of the substrate is smaller than the density of pores adjacent to the edge portion of the substrate.

11. The substrate structure according to claim 1, wherein a density of pores increases from the partition wall adjacent to one end of the substrate to the partition wall adjacent to another end of the substrate.

12. The substrate structure according to claim 1, wherein a density of pores decreases from the partition wall adjacent to a central portion of the substrate to the partition wall adjacent to an edge portion of the substrate.

13. A display device having a semiconductor light emitting device comprising:
a substrate structure for transferring a pixel semiconductor light emitting device of claim 1; and
a semiconductor light emitting device disposed within the assembly hole;

14. The display device according to claim 13,
wherein the partition wall comprises a first area disposed close to the substrate and a second area disposed far from the substrate, depending on the height from the substrate and
wherein a density of pores of the first area and a density of pores of the second area are different.

15. The display device according to claim 14, wherein a size of pores in the first area is larger than a size of pores in the second area.

16. The display device according to claim 14, wherein a number of pores in the first area is greater than a number of pores in the second area.

17. The display device according to claim 14, wherein a size of pores in the first area is smaller than a size of pores in the second area.

18. The display device according to claim 14, wherein a number of pores in the first area is less than a number of pores in the second area.

19. The display device according to claim 13, wherein a concavo-convex structure is formed on a surface of the partition wall due to the porous structure.

20. The display device according to claim 13, wherein a density of pores adjacent to a central portion of the substrate is different from a density of pores adjacent to an edge portion of the substrate.
